(19) United States
(12) Patent Application Publication
(10) Pub. No.: US 2024/0193224 A1
(43) Pub. Date: Jun. 13, 2024

(54) METHOD FOR CONTROLLING NAND FLASH MEMORY TO IMPLEMENT CONVOLUTION OPERATION

(71) Applicant: UNIM Innovation (Wuxi) Co., Ltd., Wuxi (CN)

(72) Inventor: QIANG TANG, Wuxi (CN)

(73) Assignee: UNIM Innovation (Wuxi) Co., Ltd., Wuxi (CN)

(21) Appl. No.: 18/525,153

(22) Filed: Nov. 30, 2023

(30) Foreign Application Priority Data
Dec. 13, 2022 (CN) 202211592539.1

(51) Int. Cl. G06F 17/15; H03K 19/21

(52) U.S. Cl. CPC G06F 17/15; H03K 19/21

(57) ABSTRACT

The present invention provides a method for controlling a NAND flash memory to implement a convolution operation, including: performing an XNOR operation on multiple pieces of first data and data associated with the multiple pieces of first data by a NAND flash memory, and obtaining a sum of XNOR operation results; and obtaining a convolution operation result according to the sum of the XNOR operation results and a total amount of the first data, or performing an XOR operation on multiple pieces of second data and data associated with the multiple pieces of second data by the NAND flash memory, obtaining a sum of XOR operation results, and obtaining a convolution operation result according to the sum of the XNOR operation results and the sum of the XOR operation results, where the first data and the second data have same bits and are mutually inverted data, and the data associated with the second data and the data associated with the first data are mutually inverted data. The convolution operation is implemented by the NAND flash memory, which avoids interference of “0”.

### TECHNICAL FIELD

The present invention relates to the technical field of NAND flash memories, in particular to a method for controlling a NAND flash memory to implement a convolution operation.

### BACKGROUND

In order to realize a binary neural network, it is required to calculate a sum of “+1” XNOR results and then subtract a sum of “−1” XNOR results. However, a NAND flash memory can only sense “+1”, and “−1” will be detected as “0”, so a convolution operation cannot be implemented by the NAND flash memory.

Therefore, it is necessary to provide a novel method for controlling a NAND flash memory to implement a convolution operation, to solve the above problem in the prior art.

### SUMMARY

An objective of the present invention is to provide a method for controlling a NAND flash memory to implement a convolution operation, where the convolution operation is implemented by the NAND flash memory.

To achieve the above objective, the method for controlling a NAND flash memory to implement a convolution operation according to the present invention includes the following steps:
S1: performing an XNOR operation on multiple pieces of first data and data associated with the multiple pieces of first data by a NAND flash memory, and obtaining a sum of XNOR operation results; and
S2: obtaining a convolution operation result according to the sum of the XNOR operation results and a total amount of the first data, or performing an XOR operation on multiple pieces of second data and data associated with the multiple pieces of second data by the NAND flash memory, obtaining a sum of XOR operation results, and obtaining a convolution operation result according to the sum of the XNOR operation results and the sum of the XOR operation results, where the first data and the second data have same bits and are mutually inverted data, and the data associated with the second data and the data associated with the first data are mutually inverted data.

The method for controlling a NAND flash memory to implement a convolution operation has the following beneficial effects: the XNOR operation is performed on the multiple pieces of first data and the data associated with the multiple pieces of first data by the NAND flash memory, and the sum of the XNOR operation results is obtained; and the convolution operation result is obtained according to the sum of the XNOR operation results and the total amount of the first data, or the XOR operation is performed on the multiple pieces of second data and the data associated with the multiple pieces of second data by the NAND flash memory, the sum of the XOR operation results is obtained, and the convolution operation result is obtained according to the sum of the XNOR operation results and the sum of the XOR operation results. The convolution operation is implemented by the NAND flash memory, which avoids interference of “0”.

Optionally, the obtaining a convolution operation result according to the sum of the XNOR operation results and a total amount of the first data includes:
subtracting the total amount of the first data from twice the sum of the XNOR operation results, to obtain the convolution operation result.

Optionally, the obtaining a convolution operation result according to the sum of the XNOR operation results and the sum of the XOR operation results includes:
subtracting the sum of the XOR operation results from the sum of the XNOR operation results by an external circuit, to obtain the convolution operation result.

Optionally, the obtaining a convolution operation result according to the sum of the XNOR operation results and the sum of the XOR operation results includes:
determining the sum of the XNOR operation results and the sum of the XOR operation results;
if the sum of the XNOR operation results is greater than the sum of the XOR operation results,
applying a voltage corresponding to the sum of the XNOR operation results to page buffers of the NAND flash memory, to be applied to bit lines; and
performing the XOR operation on the multiple pieces of second data and the data associated with the multiple pieces of second data by the NAND flash memory, to subtract the sum of the XOR operation results from the sum of the XNOR operation results, to obtain the convolution operation result.

Optionally, the obtaining a convolution operation result according to the sum of the XNOR operation results and the sum of the XOR operation results includes:
determining the sum of the XNOR operation results and the sum of the XOR operation results;
if the sum of the XNOR operation results is less than the sum of the XOR operation results,
applying a voltage corresponding to the sum of the XOR operation results to page buffers of the NAND flash memory, to be applied to bit lines; and
performing the XNOR operation on the multiple pieces of first data and the data associated with the multiple pieces of first data by the NAND flash memory, to subtract the sum of the XNOR operation results from the sum of the XOR operation results, to obtain the convolution operation result.

Optionally, the performing an XNOR operation on multiple pieces of first data and data associated with the multiple pieces of first data by a NAND flash memory, and obtaining a sum of XNOR operation results includes:
providing a NAND flash memory, where the NAND flash memory includes multiple memory blocks and multiple page buffers, each of the memory blocks includes multiple synaptic strings, multiple bit lines, and multiple word lines, each of the synaptic strings includes multiple memory cells connected in series, the synaptic strings are connected to the bit lines in a one-to-one correspondence manner, the word lines are connected to all the synaptic strings, the page buffers are connected to all the memory blocks, and one of the bit lines is connected to only one of the page buffers;
writing the multiple pieces of first data into the memory cells of the different memory blocks, respectively, and applying a voltage to the memory cells via the word lines;
and sensing, by the page buffers, a current of the memory blocks, to obtain XOR results.

Optionally, the sensing, by the page buffers, a current of the memory blocks, to obtain XOR results includes:
dividing a sensing time of the page buffers into N sections;
discharging a pre-charge voltage of the page buffers via the bit lines until the pre-charge voltage of the page buffers is less than a threshold voltage, and recoding this time period as an M^{th} section; and

obtaining the convolution result according to M and N, M and N being natural numbers greater than 0.

Optionally, the method for controlling a NAND flash memory to implement a convolution operation further includes a calibration step, where the calibration step includes:
by using a memory cell with known weight data and feature data as a reference unit, calibrating the sensing time of the page buffers with reference to a current of the reference unit that is sensed by a corresponding one of the page buffers.

### BRIEF DESCRIPTION OF THE DRAWINGS

FIG. 1 is a flowchart of a method for controlling a NAND flash memory to implement a convolution operation in some embodiments of the present invention;

FIG. 2 is a schematic structural diagram of a NAND flash memory in some embodiments of the present invention;

FIG. 3 is a schematic diagram of a circuit of a page buffer in some embodiments of the present invention;

FIG. 4 is a schematic diagram of a time sequence of the page buffer shown in FIG. 3 in some embodiments of the present invention;

FIG. 5 is a schematic diagram of a circuit of a page buffer in some other embodiments of the present invention;

FIG. 6 is a schematic diagram of a time sequence of the page buffer shown in FIG. 5 in some embodiments of the present invention;

FIG. 7 is a schematic structural diagram of a NAND flash memory in some embodiments of the present invention;

FIG. 8 is a schematic diagram of a threshold voltage range for a memory cell in some embodiments of the present invention;

FIG. 9 is a schematic diagram of a threshold voltage range for a first drain-side selector in some embodiments of the present invention;

FIG. 10 is a schematic diagram of a threshold voltage range for a memory cell in yet some embodiments of the present invention; and

FIG. 11 is a schematic diagram of a threshold voltage range for a first drain-side selector in yet some embodiments of the present invention.

### DESCRIPTION OF THE EMBODIMENTS

To make the objectives, technical solutions and advantages of the present disclosure more clearly, the following clearly and completely describes the technical solutions in the embodiments of the present disclosure with reference to the accompanying drawings in the embodiments of the present disclosure. Apparently, the described embodiments are merely a part rather than all of the embodiments of the present disclosure. Apparently, the embodiments described are some rather than all of the embodiments of the present invention. All other embodiments obtained by a person of ordinary skill in the art based on the embodiments of the present disclosure without creative efforts shall fall within the protection scope of the present disclosure. Unless otherwise defined, technical terms or scientific terms used herein shall have their ordinary meanings as understood by those of ordinary skill in the art to which the present disclosure belongs. The similar term such as “include/comprise” used herein refers to that an element or item occurring before the term covers elements or items listed after the term and their equivalents, without excluding other elements or items.

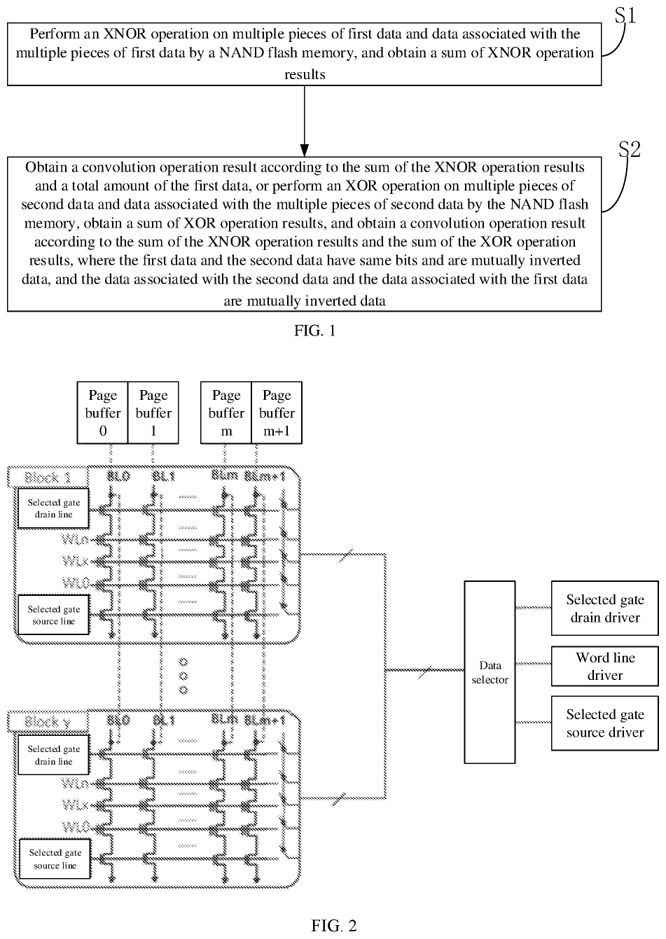

In view of the problem in the prior art, an embodiment of the present invention provides a method for controlling a NAND flash memory to implement a convolution operation. Referring to FIG. 1, the method for controlling a NAND flash memory to implement a convolution operation includes the following steps:
S1: performing an XNOR operation on multiple pieces of first data and data associated with the multiple pieces of first data by a NAND flash memory, and obtaining a sum of XNOR operation results; and
S2: obtaining a convolution operation result according to the sum of the XNOR operation results and a total amount of the first data, or performing an XOR operation on multiple pieces of second data and data associated with the multiple pieces of second data by the NAND flash memory, obtaining a sum of XOR operation results, and obtaining a convolution operation result according to the sum of the XNOR operation results and the sum of the XOR operation results, where the first data and the second data have same bits and are mutually inverted data, and the data associated with the second data and the data associated with the first data are mutually inverted data.

FIG. 2 is a schematic structural diagram of a NAND flash memory according to some embodiments of the present invention. Referring to FIG. 2, the NAND flash memory includes y memory blocks and m+2 page buffers. Each of the memory blocks includes m+2 synaptic strings, m+2 bit lines (BLs), three word lines (WLs), a selected gate drain (SGD) line, and a selected gate source (SGS) line. Each of the synaptic strings includes a drain-side selector, a source-side selector, and three memory cells. The three memory cells are a first memory cell, a second memory cell, and a third memory cell, respectively. The drain-side selector, the first memory cell, the second memory cell, the third memory cell, and the source-side selector are sequentially connected in series. The drain-side selector in a first synaptic string is connected to a first bit line BL0, and the drain-side selector in a second synaptic string is connected to a second bit line BL1. By analog, the drain-side selector in an (m+1)^{th} synaptic string is connected to an (m+1)^{th} bit line BLm, and the drain-side selector in an (m+2)^{th} synaptic string is connected to an (m+2)^{th} bit line BLm+1.

Referring to FIG. 2, first bit lines BL0 of a first memory block block1, first bit lines BL0 of a second memory block to first bit lines BL0 of a y^{th} memory block are all connected to a first page buffer, and second bit lines BL1 of the first memory block, second bit lines BL1 of the second memory block to second bit lines BL1 of the y^{th} memory block are all connected to a second page buffer. By analog, (m+1)^{th} bit lines BLm of the first memory block, (m+1)^{th} bit lines BLm of the second memory block to (m+1)^{th} bit lines BLm of the y^{th} memory block are all connected to an (m+1)^{th} page buffer, and (m+2)^{th} bit lines BLm+1 of the first memory block, (m+2)^{th} bit lines BLm+1 of the second memory block to (m+2)^{th} bit lines BLm+1 of the y^{th} memory block blocky are all connected to an (m+2)^{th} page buffer.

Referring to FIG. 2, the NAND flash memory further includes a data selector. An output terminal of the data selector is connected to the memory blocks, a first input terminal of the data selector is connected to a selected gate drain driver, a second input terminal of the data selector is connected to a word line driver, and a third input terminal of the data selector is connected to a selected gate source driver, to transmit signals to the word lines, the selected gate drain lines, and the selected gate source lines of the different memory blocks.

In some embodiments, the obtaining a convolution operation result according to the sum of the XNOR operation results and a total amount of the first data includes: subtracting the total amount of the first data from twice the sum of the XNOR operation results, to obtain the convolution operation result.

In some specific embodiments, the first data includes A1, A2, A3, and A4, and the total amount of the first data is 4. When A1=1, B1=1, A2=0, B2=1, A3=1, B3=0, A4=0, B4=0, A1 XNOR B1=1, A2 XNOR B2=0, A3 XNOR B3=0, and A4 XNOR B4=1, the sum of the XNOR operation results is (A1 XNOR B1)+(A2 XNOR B2)+(A3 XNOR B3)+(A4 XNOR B4)=2.4 is subtracted from twice 2 to obtain 0, such that the convolution operation result is 0. Thus, it can be seen that 0 is converted into −1.

In some embodiments, the obtaining a convolution operation result according to the sum of the XNOR operation results and the sum of the XOR operation results includes: subtracting the sum of the XOR operation results from the sum of the XNOR operation results by an external circuit, to obtain the convolution operation result.

In some specific embodiments, the first data includes A1, A2, A3, and A4. When A1=1, B1=1, A2=0, B2=1, A3=1, B3=0, A4=0, B4=0, A1 XNOR B1=1, A2 XNOR B2=0, A3 XNOR B3=0, and A4 XNOR B4=1, the sum of the XNOR operation results is (A1 XNOR B1)+(A2 XNOR B2)+(A3 XNOR B3)+(A4 XNOR B4)=2. The second data includes A11, A22, A33, and A44. When A11=0, B11=0, A22=1, B22=0, A33=0, B33=1, A44=1, B44=1, A11 XOR B11=0, A22 XOR B22=1, A33 XOR B33=1, and A44 XOR B44=0, the sum of the XOR operation results is (A11 XOR B11)+(A22 XOR B22)+(A33 XOR B33)+(A44 XOR B44)=2.2-2=0, such that the convolution operation result is 0. Thus, it can be seen that 0 is converted into−1.

In some embodiments, the obtaining a convolution operation result according to the sum of the XNOR operation results and the sum of the XOR operation results includes:
determining the sum of the XNOR operation results and the sum of the XOR operation results;
if the sum of the XNOR operation results is greater than the sum of the XOR operation results,
applying a voltage corresponding to the sum of the XNOR operation results to page buffers of the NAND flash memory, to be applied to bit lines; and
performing the XOR operation on the multiple pieces of second data and the data associated with the multiple pieces of second data by the NAND flash memory, to subtract the sum of the XOR operation results from the sum of the XNOR operation results, to obtain the convolution operation result.

In some embodiments, the obtaining a convolution operation result according to the sum of the XNOR operation results and the sum of the XOR operation results includes:
determining the sum of the XNOR operation results and the sum of the XOR operation results;
if the sum of the XNOR operation results is less than the sum of the XOR operation results,
applying a voltage corresponding to the sum of the XOR operation results to page buffers of the NAND flash memory, to be applied to bit lines; and
performing the XNOR operation on the multiple pieces of first data and the data associated with the multiple pieces of first data by the NAND flash memory, to subtract the sum of the XNOR operation results from the sum of the XOR operation results, to obtain the convolution operation result.

In some embodiments, the performing an XNOR operation on multiple pieces of first data and data associated with the multiple pieces of first data by a NAND flash memory, and obtaining a sum of XNOR operation results includes:
providing a NAND flash memory, where the NAND flash memory includes multiple memory blocks and multiple page buffers, each of the memory blocks includes multiple synaptic strings, multiple bit lines, and multiple word lines, each of the synaptic strings includes multiple memory cells connected in series, the synaptic strings are connected to the bit lines in a one-to-one correspondence manner, the word lines are connected to all the synaptic strings, the page buffers are connected to all the memory blocks, and one of the bit lines is connected to only one of the page buffers;
writing the multiple pieces of first data into the memory cells of the different memory blocks, respectively, and applying a voltage to the memory cells via the word lines; and
sensing, by the page buffers, a current of the memory blocks, to obtain XOR results.

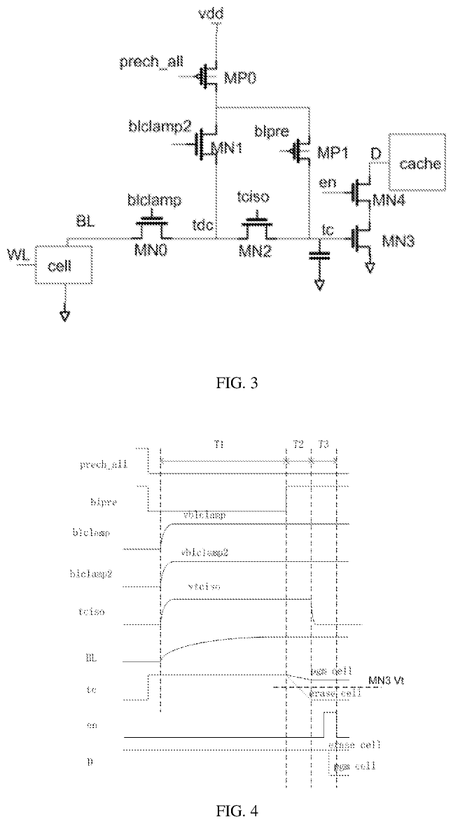

FIG. 3 is a schematic diagram of a circuit of a page buffer according to some embodiments of the present invention. Referring to FIG. 3, the page buffer includes a first P-channel metal oxide semiconductor (PMOS) transistor MP0, a second PMOS transistor MP1, a first N-channel metal oxide semiconductor (NMOS) transistor MN0, a second NMOS transistor MN1, a third NMOS transistor MN2, a fourth NMOS transistor MN3, a fifth NMOS transistor MN4, a capacitor C, and a cache. A source of the first PMOS transistor MP0 is connected to a power supply voltage vdd. A gate of the first PMOS transistor MP0 is connected to a first control signal prech_all. A drain of the first PMOS transistor MP0 is connected to a drain of the second NMOS transistor MN1 and a source of the second PMOS transistor MP1. A gate of the second NMOS transistor MN1 is connected to a second control signal blclamp2. A gate of the second PMOS transistor MP1 is connected to a third control signal blpre. A source of the second NMOS transistor MN1 is connected to a drain of the first NMOS transistor MN0 and a source of the third NMOS transistor MN2, with tdc as a connection point. A gate of the first NMOS transistor MN0 is connected to a fourth control signal blclamp. A source of the first NMOS transistor MN0 is connected to a bit line BL. A gate of the third NMOS transistor MN2 is connected to a fifth control signal tciso. A drain of the second PMOS transistor MP1 is connected to a gate of the fourth NMOS transistor MN3, one terminal of the capacitor C, and a drain of the third NMOS transistor MN2, with tc as a connection point. The other terminal of the capacitor C and a source of the fourth NMOS transistor MN3 are connected to ground. A drain of the fourth NMOS transistor MN3 is connected to a source of the fifth NMOS transistor MN4. A drain D of the fifth NMOS transistor MN4 is connected to the cache. A gate of the fifth NMOS transistor MN4 is connected to a sixth control signal en.

FIG. 4 is a schematic diagram of a time sequence of the page buffer in FIG. 3 according to some embodiments of the present invention. In FIG. 4, T1 represents a first stage, T2 represents a second stage, T3 represents a third stage, MN3 Vt represents a threshold voltage of the fourth NMOS transistor, pgm cell represents a memory cell in a programmed state, erase cell represents a memory cell in an erased state, vblclamp represents a voltage when the fourth control signal is at a high level, vblclamp2 represents a voltage when the second control signal blclamp2 is at a high level, and vtciso represents a voltage when the fifth control signal is at a high level.

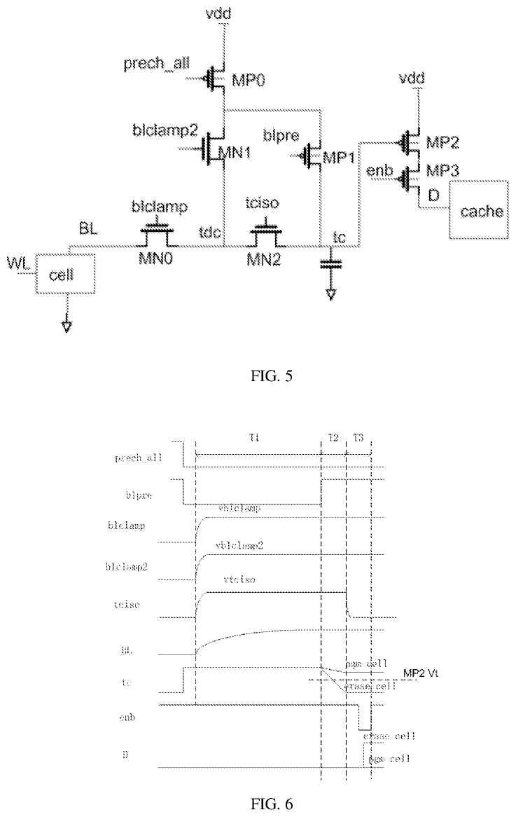

FIG. 5 is a schematic diagram of a circuit of a page buffer according to some other embodiments of the present invention. Referring to FIG. 5, the page buffer includes a first PMOS transistor MP0, a second PMOS transistor MP1, a third PMOS transistor MP2, a fourth PMOS transistor MP3, a first NMOS transistor MN0, a second NMOS transistor MN1, a third NMOS transistor MN2, a capacitor C, and a cache. A source of the first PMOS transistor MP0 is connected to a power supply voltage vdd. A gate of the first PMOS transistor MP0 is connected to a first control signal prech_all. A drain of the first PMOS transistor MP0 is connected to a drain of the second NMOS transistor MN1 and a source of the second PMOS transistor MP1. A gate of the second NMOS transistor MN1 is connected to a second control signal blclamp2. A gate of the second PMOS transistor MP1 is connected to a third control signal blpre. A source of the second NMOS transistor MN1 is connected to a drain of the first NMOS transistor MN0 and a source of the third NMOS transistor MN2, with tdc as a connection point. A gate of the first NMOS transistor MN0 is connected to a fourth control signal blclamp. A source of the first NMOS transistor MN0 is connected to a bit line BL. A gate of the third NMOS transistor MN2 is connected to a fifth control signal tciso. A drain of the second PMOS transistor MP1 is connected to a gate of the third PMOS transistor MP3, one terminal of the capacitor C, and a drain of the third NMOS transistor MN2, with tc as a connection point. The other terminal of the capacitor C is connected to ground. A source of the third PMOS transistor MP2 is connected to the power supply voltage vdd. A drain of the third PMOS transistor MP2 is connected to a source of the fourth PMOS transistor MP3. A drain D of the fourth PMOS transistor MP3 is connected to the cache. A gate of the fourth PMOS transistor MP3 is connected to a sixth control signal enb.

FIG. 6 is a schematic diagram of a time sequence of the page buffer in FIG. 5 according to some embodiments of the present invention. In FIG. 6, T1 represents a first stage, T2 represents a second stage, T3 represents a third stage, MP2 Vt represents a threshold voltage of the third PMOS transistor, pgm cell represents a memory cell in a programmed state, erase cell represents a memory cell in an erased state, vblclamp represents a voltage when the fourth control signal is at a high level, vblclamp2 represents a voltage when the second control signal blclamp2 is at a high level, and vtciso represents a voltage when the fifth control signal is at a high level.

In some embodiments, the sensing, by the page buffers, a current of the memory blocks, to obtain XOR results includes: dividing a sensing time of the page buffers into N sections; discharging a pre-charge voltage of the page buffers via the bit lines until the pre-charge voltage of the page buffers is less than a threshold voltage, and recoding this time period as an Mt section; and obtaining the convolution result according to M and N, M and N being natural numbers greater than 0. Referring to FIG. 5, a voltage at the connection point tc is the pre-charge voltage of the page buffers, and the threshold voltage is a threshold voltage of the fourth NMOS transistor. Sections before the M^{th} section represent 0, and the M^{th} section and sections thereafter represent 1. In some specific embodiments, for example, when N is 10 and M is 5, a sub-convolution result is 0000111111.

In some embodiments, the method for controlling a NAND flash memory to implement a convolution operation further includes a calibration step, where the calibration step includes: by using a memory cell with known weight data and feature data as a reference unit, calibrating the sensing time of the page buffers with reference to a current of the reference unit that is sensed by a corresponding one of the page buffers.

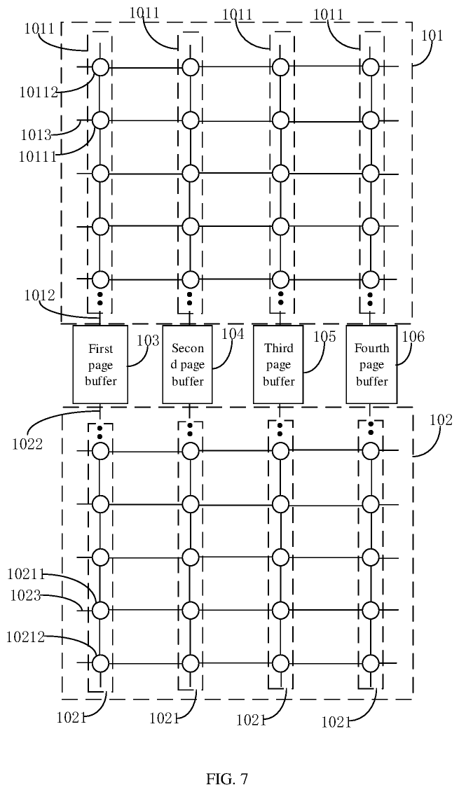

FIG. 7 is a schematic structural diagram of a NAND flash memory according to some embodiments of the present invention. Referring to FIG. 7, the NAND flash memory includes a first memory block 101, a second memory block 102, a first page buffer 103, a second page buffer 104, a third page buffer 105, and a fourth page buffer 106.

Referring to FIG. 7, the first memory block 101 includes four first synaptic strings 1011, four first bit lines 1012, and four first word lines 1013. The second memory block 102 includes four second synaptic strings 1021, four second bit lines 1022, and four second word lines 1023. Each of the first synaptic strings 1011 includes four first memory cells 10111 connected in series and a first drain-side selector 10112. Each of the second synaptic strings 1021 includes four second memory cells 10211 connected in series and a second drain-side selector 10212.

Referring to FIG. 7, a first one of the first synaptic strings 1011 is connected to the first page buffer 103 via a first one of the first bit lines 1012. A first one of the second synaptic strings 1021 is connected to the first page buffer 103 via a first one of the second bit lines 1022. A second one of the first synaptic strings 1011 is connected to the second page buffer 104 via a second one of the first bit lines 1012. A second one of the second synaptic strings 1021 is connected to the second page buffer 104 via a second one of the second bit lines 1022. A third one of the first synaptic strings 1011 is connected to the third page buffer 105 via a third one of the first bit lines 1012. A third one of the second synaptic strings 1021 is connected to the third page buffer 105 via a third one of the second bit lines 1022. A fourth one of the first synaptic strings 1011 is connected to the fourth page buffer 106 via a fourth one of the first bit lines 1012. A fourth one of the second synaptic strings 1021 is connected to the fourth page buffer 106 via a fourth one of the second bit lines 1022.

Referring to FIG. 7, a first one of the first word lines 1013 is connected to a first one of the first memory cells 10111 of the first one of the first synaptic strings 1011, a first one of the first memory cells 10111 of the second one of the first synaptic strings 1011, a first one of the first memory cells 10111 of the third one of the first synaptic strings 1011, and a first one of the first memory cells 10111 of the fourth one of the first synaptic strings 1011. A second one of the first word lines 1013 is connected to a second one of the first memory cells 10111 of the first one of the first synaptic strings 1011, a second one of the first memory cells 10111 of the second one of the first synaptic strings 1011, a second one of the first memory cells 10111 of the third one of the first synaptic strings 1011, and a second one of the first memory cells 10111 of the fourth one of the first synaptic strings 1011. A third one of the first word lines 1013 is connected to a third one of the first memory cells 10111 of the first one of the first synaptic strings 1011, a third one of the first memory cells 10111 of the second one of the first synaptic strings 1011, a third one of the first memory cells 10111 of the third one of the first synaptic strings 1011, and a third one of the first memory cells 10111 of the fourth one of the first synaptic strings 1011. A fourth one of the first word lines 1013 is connected to a fourth one of the first memory cells 10111 of the first one of the first synaptic strings 1011, a fourth one of the first memory cells 10111 of the second one of the first synaptic strings 1011, a fourth one of the first memory cells 10111 of the third one of the first synaptic strings 1011, and a fourth one of the first memory cells 10111 of the fourth one of the first synaptic strings 1011.

Referring to FIG. 7, a first one of the second word lines 1023 is connected to a first one of the second memory cells 10211 of the first one of the second synaptic strings 1021, a first one of the second memory cells 10211 of the second one of the second synaptic strings 1021, a first one of the second memory cells 10211 of the third one of the second synaptic strings 1021, and a first one of the second memory cells 10211 of the fourth one of the second synaptic strings 1021. A second one of the second word lines 1023 is connected to a second one of the second memory cells 10211 of the first one of the second synaptic strings 1021, a second one of the second memory cells 10211 of the second one of the second synaptic strings 1021, a second one of the second memory cells 10211 of the third one of the second synaptic strings 1021, and a second one of the second memory cells 10211 of the fourth one of the second synaptic strings 1021. A third one of the second word lines 1023 is connected to a third one of the second memory cells 10211 of the first one of the second synaptic strings 1021, a third one of the second memory cells 10211 of the second one of the second synaptic strings 1021, a third one of the second memory cells 10211 of the third one of the second synaptic strings 1021, and a third one of the second memory cells 10211 of the fourth one of the second synaptic strings 1021. A fourth one of the second word lines 1023 is connected to a fourth one of the second memory cells 10211 of the first one of the second synaptic strings 1021, a fourth one of the second memory cells 10211 of the second one of the second synaptic strings 1021, a fourth one of the second memory cells 10211 of the third one of the second synaptic strings 1021, and a fourth one of the second memory cells 10211 of the fourth one of the second synaptic strings 1021.

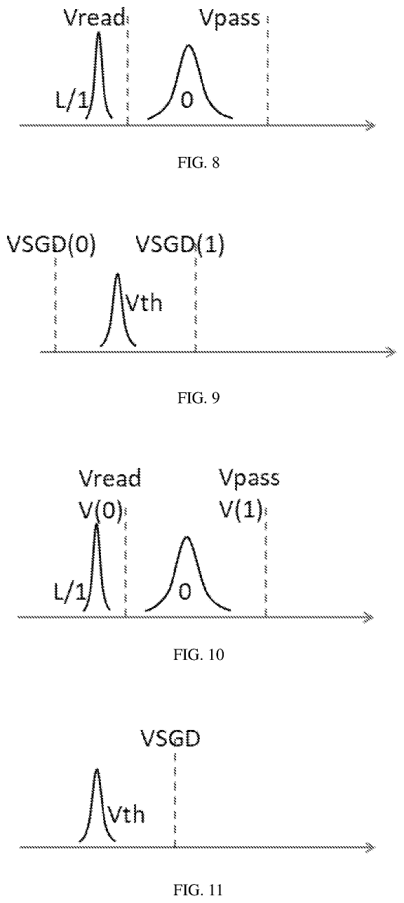

FIG. 8 is a schematic diagram of a threshold voltage range for a memory cell in some embodiments of the present invention. Reference is made to FIG. 8, in which L/1 represents a first threshold voltage, 0 represents a second threshold voltage, Vread represents a first potential voltage, and Vpass represents a sixth potential voltage.

FIG. 9 is a schematic diagram of a threshold voltage range for a first drain-side selector in some embodiments of the present invention. Referring to FIG. 9, VSGD (0) represents a voltage when binary data of 0 is input, and VSGD (1) represents a voltage when binary data of 1 is input. A threshold voltage of the second drain-side selector 10212 is the same as that of the first drain-side selector 10112.

In some embodiments, referring to FIG. 7, FIG. 8, and FIG. 9, first data is written into the first one of the first memory cells 10111 of the first one of the first synaptic strings 1011 of the first memory block 101, where the first data is the binary data of 0. Third data is written into the second one of the first memory cells 10111 of the first one of the first synaptic strings 1011 of the first memory block 101, where the third data is the binary data of 1. Both the third one and the fourth one of the first memory cells 10111 of the first one of the first synaptic strings 1011 of the first memory block 101 do not store data. Second data is written into the first one of the second memory cells 10211 of the first one of the second synaptic strings 1021 of the second memory block 102, where the second data is the binary data of 1. Fourth data is written into the second one of the second memory cells 10211 of the first one of the second synaptic strings 1021 of the second memory block 102, where the fourth data is the binary data of 0. Both the third one and the fourth one of the second memory cells 10211 of the first one of the first synaptic strings 1011 of the second memory block 102 do not store data. The first one of the first memory cells 10111 of the first one of the first synaptic strings 1011 of the first memory block 101 is a first memory cell to be used. The first one of the second memory cells 10211 of the first one of the second synaptic strings 1021 of the second memory block 102 is a second memory cell to be used.

In some embodiments, referring to FIG. 7, FIG. 8, and FIG. 9, a threshold voltage of the first one of the first memory cells 10111 of the first one of the first synaptic strings 1011 of the first memory block 101 is set as the second threshold voltage. A threshold voltage of the second one of the first memory cells 10111 of the first one of the first synaptic strings 1011 of the first memory block 101 is set as the first threshold voltage. A threshold voltage of the third one and the fourth one of the first memory cells 10111 of the first one of the first synaptic strings 1011 of the first memory block 101 is set as the first threshold voltage. A threshold voltage of the first one of the second memory cells 10211 of the first one of the second synaptic strings 1021 of the second memory block 102 is set as the first threshold voltage. A threshold voltage of the second one of the second memory cells 10211 of the first one of the second synaptic strings 1021 of the second memory block 102 is set as the second threshold voltage. A threshold voltage of the third one and the fourth one of the second memory cells 10211 of the first one of the first synaptic strings 1011 of the second memory block 102 is set as the first threshold voltage.

In some embodiments, referring to FIG. 7, FIG. 8, and FIG. 9, a second potential voltage is applied to the first drain-side selector 10112, where a magnitude of the second potential voltage is VSGD (0), equivalently, a binary value of 0 for the XNOR operation is provided. A third potential voltage is applied to the second drain-side selector 10212, where a magnitude of the third potential voltage is VSGD (1). The first potential voltage is applied to the first one of the first word lines 1013. A fourth potential voltage is applied to the second one of the first word lines 1013. The sixth potential voltage is applied to the third one and the fourth one of the first word lines 1013. The first potential voltage is applied to the first one of the second word lines 1023. A fifth potential voltage is applied to the second one of the second word lines 1023. The sixth potential voltage is applied to the third one and the fourth one of the second word lines 1023. The data is read from the first one of the first synaptic strings 1011 of the first memory block 101 and the first one of the second synaptic strings 1021 of the second memory block 102 by the first page buffer 103, to obtain result data, where the result data is 1, that is, the XNOR operation of the binary data of 0 and the binary data of 0 is implemented by the NAND flash memory.

In yet some embodiments, referring to FIG. 7, FIG. 8, and FIG. 9, first data is written into the first one of the first memory cells 10111 of the first one of the first synaptic strings 1011 of the first memory block 101, where the first data is the binary data of 1. Third data is written into the second one of the first memory cells 10111 of the first one of the first synaptic strings 1011 of the first memory block 101, where the third data is the binary data of 1. Both the third one and the fourth one of the first memory cells 10111 of the first one of the first synaptic strings 1011 of the first memory block 101 do not store data. Second data is written into the first one of the second memory cells 10211 of the first one of the second synaptic strings 1021 of the second memory block 102, where the second data is the binary data of 0. Fourth data is written into the second one of the second memory cells 10211 of the first one of the second synaptic strings 1021 of the second memory block 102, where the fourth data is the binary data of 0. Both the third one and the fourth one of the second memory cells 10211 of the first one of the first synaptic strings 1011 of the second memory block 102 do not store data. The first one of the first memory cells 10111 of the first one of the first synaptic strings 1011 of the first memory block 101 is a first memory cell to be used. The first one of the second memory cells 10211 of the first one of the second synaptic strings 1021 of the second memory block 102 is a second memory cell to be used.

In yet some embodiments, referring to FIG. 7, FIG. 8, and FIG. 9, a threshold voltage of the first one of the first memory cells 10111 of the first one of the first synaptic strings 1011 of the first memory block 101 is set as the first threshold voltage. A threshold voltage of the second one of the first memory cells 10111 of the first one of the first synaptic strings 1011 of the first memory block 101 is set as the first threshold voltage. A threshold voltage of the third one and the fourth one of the first memory cells 10111 of the first one of the first synaptic strings 1011 of the first memory block 101 is set as the first threshold voltage. A threshold voltage of the first one of the second memory cells 10211 of the first one of the second synaptic strings 1021 of the second memory block 102 is set as the second threshold voltage. A threshold voltage of the second one of the second memory cells 10211 of the first one of the second synaptic strings 1021 of the second memory block 102 is set as the second threshold voltage. A threshold voltage of the third one and the fourth one of the second memory cells 10211 of the first one of the first synaptic strings 1011 of the second memory block 102 is set as the first threshold voltage.

In yet some embodiments, referring to FIG. 7, FIG. 8, and FIG. 9, a second potential voltage is applied to the first drain-side selector 10112, where a magnitude of the second potential voltage is VSGD (1), equivalently, a binary value of 1 for the XNOR operation is provided. A third potential voltage is applied to the second drain-side selector 10212, where a magnitude of the third potential voltage is VSGD (0). The first potential voltage is applied to the first one of the first word lines 1013. A fourth potential voltage is applied to the second one of the first word lines 1013. The sixth potential voltage is applied to the third one and the fourth one of the first word lines 1013. The first potential voltage is applied to the first one of the second word lines 1023. A fifth potential voltage is applied to the second one of the second word lines 1023. The sixth potential voltage is applied to the third one and the fourth one of the second word lines 1023. The data is read from the first one of the first synaptic strings 1011 of the first memory block 101 and the first one of the second synaptic strings 1021 of the second memory block 102 by the first page buffer 103, to obtain result data, where the result data is 1, that is, the XNOR operation of the binary data of 1 and the binary data of 1 is implemented by the NAND flash memory.

FIG. 10 is a schematic diagram of a threshold voltage range for a memory cell in yet some embodiments of the present invention. Reference is made to FIG. 10, in which L/1 represents a first threshold voltage, 0 represents a second threshold voltage, Vread represents a first potential voltage, Vpass represents a sixth potential voltage, V (0) represents a voltage when binary data of 0 is input, and V (1) represents a voltage when binary data of 1 is input.

FIG. 11 is a schematic diagram of a threshold voltage range for a first drain-side selector in yet some embodiments of the present invention. Referring to FIG. 11, Vth represents the threshold voltage range for the first drain-side selector 10112, and VSGD represents a second potential voltage that is greater than a threshold voltage of the first drain-side selector 10112. A threshold voltage of the second drain-side selector 10212 is the same as that of the first drain-side selector 10112. The third potential voltage is the same as the second potential voltage.

In some embodiments, referring to FIG. 7, FIG. 10, and FIG. 11, first data is written into the first one of the first memory cells 10111 of the first one of the first synaptic strings 1011 of the first memory block 101, where the first data is the binary data of 0. Third data is written into the second one of the first memory cells 10111 of the first one of the first synaptic strings 1011 of the first memory block 101, where the third data is the binary data of 0. Both the third one and the fourth one of the first memory cells 10111 of the first one of the first synaptic strings 1011 of the first memory block 101 do not store data. Second data is written into the first one of the second memory cells 10211 of the first one of the second synaptic strings 1021 of the second memory block 102, where the second data is the binary data of 1. Fourth data is written into the second one of the second memory cells 10211 of the first one of the second synaptic strings 1021 of the second memory block 102, where the fourth data is the binary data of 0. Both the third one and the fourth one of the second memory cells 10211 of the first one of the first synaptic strings 1011 of the second memory block 102 do not store data. The first one of the first memory cells 10111 of the first one of the first synaptic strings 1011 of the first memory block 101 is a first memory cell to be used. The first one of the second memory cells 10211 of the first one of the second synaptic strings 1021 of the second memory block 102 is a second memory cell to be used.

In some embodiments, referring to FIG. 7, FIG. 10, and FIG. 11, a threshold voltage of the first one of the first memory cells 10111 of the first one of the first synaptic strings 1011 of the first memory block 101 is set as the second threshold voltage. A threshold voltage of the second one of the first memory cells 10111 of the first one of the first synaptic strings 1011 of the first memory block 101 is set as the second threshold voltage. A threshold voltage of the third one and the fourth one of the first memory cells 10111 of the first one of the first synaptic strings 1011 of the first memory block 101 is set as the first threshold voltage. A threshold voltage of the first one of the second memory cells 10211 of the first one of the second synaptic strings 1021 of the second memory block 102 is set as the first threshold voltage. A threshold voltage of the second one of the second memory cells 10211 of the first one of the second synaptic strings 1021 of the second memory block 102 is set as the second threshold voltage. A threshold voltage of the third one and the fourth one of the second memory cells 10211 of the first one of the first synaptic strings 1011 of the second memory block 102 is set as the first threshold voltage.

In some embodiments, referring to FIG. 7, FIG. 10, and FIG. 11, a second potential voltage is applied to the first drain-side selector 10112, where a magnitude of the second potential voltage is VSGD. A third potential voltage is applied to the second drain-side selector 10212, where a magnitude of the third potential voltage is VSGD. The first potential voltage is applied to the first one of the first word lines 1013. A fourth potential voltage is applied to the second one of the first word lines 1013, where a magnitude of the fourth potential voltage is V (0), equivalently, the binary data of 0 for the XNOR operation is provided. The sixth potential voltage is applied to the third one and the fourth one of the first word lines 1013. The first potential voltage is applied to the first one of the second word lines 1023. A fifth potential voltage is applied to the second one of the second word lines 1023, where a magnitude of the fifth potential voltage is V (1). The sixth potential voltage is applied to the third one and the fourth one of the second word lines 1023. The data is read from the first one of the first synaptic strings 1011 of the first memory block 101 and the first one of the second synaptic strings 1021 of the second memory block 102 by the first page buffer 103, to obtain result data, where the result data is 1, that is, the XNOR operation of the binary data of 0 and the binary data of 0 is implemented by the NAND flash memory.

In yet some embodiments, referring to FIG. 7, FIG. 10, and FIG. 11, first data is written into the first one of the first memory cells 10111 of the first one of the first synaptic strings 1011 of the first memory block 101, where the first data is the binary data of 1. Third data is written into the second one of the first memory cells 10111 of the first one of the first synaptic strings 1011 of the first memory block 101, where the third data is the binary data of 0. Both the third one and the fourth one of the first memory cells 10111 of the first one of the first synaptic strings 1011 of the first memory block 101 do not store data. Second data is written into the first one of the second memory cells 10211 of the first one of the second synaptic strings 1021 of the second memory block 102, where the second data is the binary data of 0. Fourth data is written into the second one of the second memory cells 10211 of the first one of the second synaptic strings 1021 of the second memory block 102, where the fourth data is the binary data of 0. Both the third one and the fourth one of the second memory cells 10211 of the first one of the first synaptic strings 1011 of the second memory block 102 do not store data. The first one of the first memory cells 10111 of the first one of the first synaptic strings 1011 of the first memory block 101 is a first memory cell to be used. The first one of the second memory cells 10211 of the first one of the second synaptic strings 1021 of the second memory block 102 is a second memory cell to be used.

In yet some embodiments, referring to FIG. 7, FIG. 10, and FIG. 11, a threshold voltage of the first one of the first memory cells 10111 of the first one of the first synaptic strings 1011 of the first memory block 101 is set as the first threshold voltage. A threshold voltage of the second one of the first memory cells 10111 of the first one of the first synaptic strings 1011 of the first memory block 101 is set as the second threshold voltage. A threshold voltage of the third one and the fourth one of the first memory cells 10111 of the first one of the first synaptic strings 1011 of the first memory block 101 is set as the first threshold voltage. A threshold voltage of the first one of the second memory cells 10211 of the first one of the second synaptic strings 1021 of the second memory block 102 is set as the second threshold voltage. A threshold voltage of the second one of the second memory cells 10211 of the first one of the second synaptic strings 1021 of the second memory block 102 is set as the second threshold voltage. A threshold voltage of the third one and the fourth one of the second memory cells 10211 of the first one of the first synaptic strings 1011 of the second memory block 102 is set as the first threshold voltage.

In yet some embodiments, referring to FIG. 7, FIG. 10, and FIG. 11, a second potential voltage is applied to the first drain-side selector 10112, where a magnitude of the second potential voltage is VSGD, equivalently, a binary value of 0 for the XNOR operation is provided. A third potential voltage is applied to the second drain-side selector 10212, where a magnitude of the third potential voltage is VSGD. The first potential voltage is applied to the first one of the first word lines 1013. A fourth potential voltage is applied to the second one of the first word lines 1013, where a magnitude of the fourth potential voltage is V (1), equivalently, the binary data of 1 for the XNOR operation is provided. The sixth potential voltage is applied to the third one and the fourth one of the first word lines 1013. The first potential voltage is applied to the first one of the second word lines 1023. A fifth potential voltage is applied to the second one of the second word lines 1023, where a magnitude of the fifth potential voltage is V (0). The sixth potential voltage is applied to the third one and the fourth one of the second word lines 1023. The data is read from the first one of the first synaptic strings 1011 of the first memory block 101 and the first one of the second synaptic strings 1021 of the second memory block 102 by the first page buffer 103, to obtain result data, where the result data is 1, that is, the XNOR operation of the binary data of 1 and the binary data of 1 is implemented by the NAND flash memory.

In some embodiments, the way of performing the XNOR operation via the second synaptic string 1021 of the first memory block 101, the second synaptic string 1021 of the second memory block 102, and the second page buffer 104, or performing the XNOR operation via the other synaptic strings and the corresponding page buffers is the same as the way of performing the XNOR operation via the first synaptic string 1011 of the first memory block 101, the first synaptic string 1011 of the second memory block 102, and the first page buffer 103, and thus will not be repeated herein.

While the embodiments of the present invention have been described in detail above, it is apparent to those skilled in the art that various modifications and variations can be made to these embodiments. However, it is to be understood that such modifications and variations all fall within the scope and spirit of the present invention as described in the claims. Furthermore, the present invention described herein may have other embodiments and may be carried out or implemented in various ways.

What is claimed is:

1. A method for controlling a NAND flash memory to implement a convolution operation, comprising the following steps:
S1: performing an XNOR operation on multiple pieces of first data and data associated with the multiple pieces of first data by a NAND flash memory, and obtaining a sum of XNOR operation results; and
S2: obtaining a convolution operation result according to the sum of the XNOR operation results and a total amount of the first data, or performing an XOR operation on multiple pieces of second data and data associated with the multiple pieces of second data by the NAND flash memory, obtaining a sum of XOR operation results, and obtaining a convolution operation result according to the sum of the XNOR operation results and the sum of the XOR operation results, wherein the first data and the second data have same bits and are mutually inverted data, and the data associated with the second data and the data associated with the first data are mutually inverted data.

2. The method for controlling a NAND flash memory to implement a convolution operation according to claim 1, wherein the obtaining a convolution operation result according to the sum of the XNOR operation results and a total amount of the first data comprises:
subtracting the total amount of the first data from twice the sum of the XNOR operation results, to obtain the convolution operation result.

3. The method for controlling a NAND flash memory to implement a convolution operation according to claim 1, wherein the obtaining a convolution operation result according to the sum of the XNOR operation results and the sum of the XOR operation results comprises:
subtracting the sum of the XOR operation results from the sum of the XNOR operation results by an external circuit, to obtain the convolution operation result.

4. The method for controlling a NAND flash memory to implement a convolution operation according to claim 1, wherein the obtaining a convolution operation result according to the sum of the XNOR operation results and the sum of the XOR operation results comprises:
determining the sum of the XNOR operation results and the sum of the XOR operation results;
if the sum of the XNOR operation results is greater than the sum of the XOR operation results,
applying a voltage corresponding to the sum of the XNOR operation results to page buffers of the NAND flash memory, to be applied to bit lines; and
performing the XOR operation on the multiple pieces of second data and the data associated with the multiple pieces of second data by the NAND flash memory, to subtract the sum of the XOR operation results from the sum of the XNOR operation results, to obtain the convolution operation result.

5. The method for controlling a NAND flash memory to implement a convolution operation according to claim 1, wherein the obtaining a convolution operation result according to the sum of the XNOR operation results and the sum of the XOR operation results comprises:
determining the sum of the XNOR operation results and the sum of the XOR operation results;
if the sum of the XNOR operation results is less than the sum of the XOR operation results,
applying a voltage corresponding to the sum of the XOR operation results to page buffers of the NAND flash memory, to be applied to bit lines; and
performing the XNOR operation on the multiple pieces of first data and the data associated with the multiple pieces of first data by the NAND flash memory, to subtract the sum of the XNOR operation results from the sum of the XOR operation results, to obtain the convolution operation result.

6. The method for controlling a NAND flash memory to implement a convolution operation according to claim 1, wherein the performing an XNOR operation on multiple pieces of first data and data associated with the multiple pieces of first data by a NAND flash memory, and obtaining a sum of XNOR operation results comprises:
providing a NAND flash memory, wherein the NAND flash memory comprises multiple memory blocks and multiple page buffers, each of the memory blocks comprises multiple synaptic strings, multiple bit lines, and multiple word lines, each of the synaptic strings comprises multiple memory cells connected in series, the synaptic strings are connected to the bit lines in a one-to-one correspondence manner, the word lines are connected to all the synaptic strings, the page buffers are connected to all the memory blocks, and one of the bit lines is connected to only one of the page buffers;
writing the multiple pieces of first data into the memory cells of the different memory blocks, respectively, and applying a voltage to the memory cells via the word lines; and
sensing, by the page buffers, a current of the memory blocks, to obtain XOR results.

7. The method for controlling a NAND flash memory to implement a convolution operation according to claim 6, wherein the sensing, by the page buffers, a current of the memory blocks, to obtain XOR results comprises:
dividing a sensing time of the page buffers into N sections;
discharging a pre-charge voltage of the page buffers via the bit lines until the pre-charge voltage of the page buffers is less than a threshold voltage, and recoding this time period as an M^{th} section; and
obtaining the convolution result according to M and N, M and N being natural numbers greater than 0.

8. The method for controlling a NAND flash memory to implement a convolution operation according to claim 7, further comprising a calibration step, wherein the calibration step comprises:
by using a memory cell with known weight data and feature data as a reference unit, calibrating the sensing time of the page buffers with reference to a current of the reference unit that is sensed by a corresponding one of the page buffers.
